(19) United States
(12) Patent Application Publication
(10) Pub. No.: US 2024/0315024 A1
(43) Pub. Date: Sep. 19, 2024

(54) SEMICONDUCTOR DEVICE AND METHOD OF MANUFACTURING THE SAME

(71) Applicant: Kioxia Corporation, Tokyo (JP)

(72) Inventors: Kazushi HARA, Inabe (JP); Yefei HAN, Yokkaichi (JP); Keisuke NAKATSUKA, Kobe (JP); Koichi SAKATA, Yokkaichi (JP)

(73) Assignee: Kioxia Corporation, Tokyo (JP)

(21) Appl. No.: 18/595,092

(22) Filed: Mar. 4, 2024

(30) Foreign Application Priority Data
Mar. 13, 2023 (JP) 2023-039019

(51) Int. Cl. H10B 43/27; H01L 25/00; H01L 25/065; H10B 43/35

(52) U.S. Cl. CPC H10B 43/27; H01L 25/50; H10B 43/35; H01L 25/0657

(57) ABSTRACT

In one embodiment, a semiconductor device includes a stacked film including electrode layers and first insulators alternately in a first direction, a top layer of the stacked film being a second insulator that is one of the first insulators. The device further includes a columnar portion including a third insulator, a charge storage layer, a fourth insulator and a first semiconductor layer that are sequentially provided in the stacked film. The device further includes a metal layer provided on the stacked film and the columnar portion, electrically connected to the first semiconductor layer, and including one or more layers. An upper end of the columnar portion is provided at a height between upper and lower faces of the second insulator. A lower end of a highest layer among the one or more layers is provided at a position lower than the upper face of the second insulator.

### CROSS REFERENCE TO RELATED APPLICATIONS

This application is based upon and claims the benefit of priority from the prior Japanese Patent Application No. 2023-039019, filed on Mar. 13, 2023, the entire contents of which are incorporated herein by reference.

### FIELD

Embodiments described herein relate to a semiconductor device and a method of manufacturing the same.

### BACKGROUND

When an interconnect layer such as a source layer is formed on a channel semiconductor layer of a three-dimensional semiconductor memory, the interconnect layer may not have a suitable shape.

### BRIEF DESCRIPTION OF THE DRAWINGS

FIG. 1 is a cross-sectional view illustrating the structure of a semiconductor device of a first embodiment;

FIG. 2 is an enlarged cross-sectional view illustrating the structure of the semiconductor device of the first embodiment;

FIGS. 3 to 6 are cross-sectional views illustrating a method of manufacturing the semiconductor device of the first embodiment;

FIG. 7 is a cross-sectional view illustrating the structure of the semiconductor device of the first embodiment;

FIG. 8 is a cross-sectional view illustrating the structure of a semiconductor device of a comparative example of the first embodiment;

FIGS. 9A to 12B are cross-sectional views illustrating the method of manufacturing the semiconductor device of the first embodiment;

FIGS. 13A to 16B are cross-sectional views illustrating a method of manufacturing the semiconductor device of the comparative example of the first embodiment;

FIG. 17 is a cross-sectional view illustrating the structure of the semiconductor device of the first embodiment;

FIG. 18 is a cross-sectional view illustrating the structure of a semiconductor device of a modification of the first embodiment;

FIGS. 19A and 19B are cross-sectional views illustrating the structure of a semiconductor device of a second embodiment;

FIGS. 20A and 20B are cross-sectional views illustrating the structure of a semiconductor device of a comparative example of the second embodiment;

FIGS. 21A to 22B are cross-sectional views illustrating a method of manufacturing the semiconductor device of the comparative example of the second embodiment;

FIGS. 23A to 24B are cross-sectional views illustrating the method of manufacturing the semiconductor device of the comparative example of the second embodiment;

FIGS. 25A to 26B are cross-sectional views illustrating the method of manufacturing the semiconductor device of the second embodiment; and

FIGS. 27A to 29C are cross-sectional views illustrating the detailed method of manufacturing the semiconductor device of the second embodiment.

### DETAILED DESCRIPTION

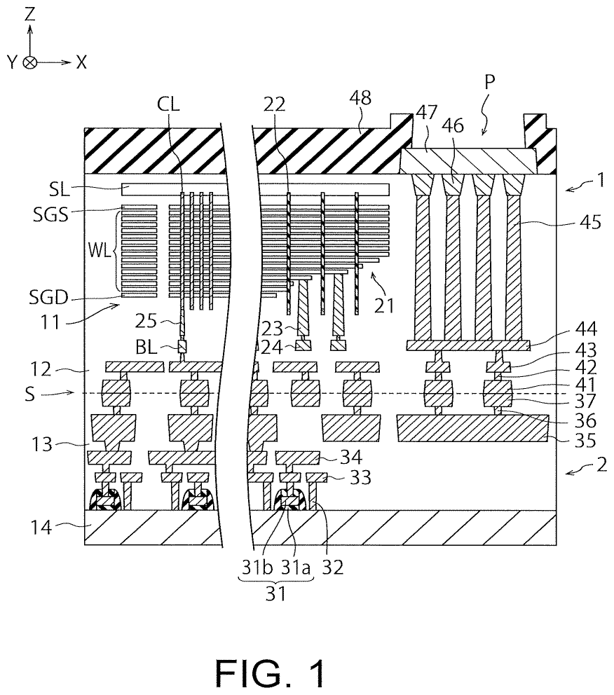

Embodiments will now be explained with reference to the accompanying drawings. The same components in FIGS. 1 to 29C are denoted by the same reference sign, and duplicate description of components is omitted.

In one embodiment, a semiconductor device includes a stacked film including a plurality of electrode layers and a plurality of first insulators alternately in a first direction, a top layer of the stacked film being a second insulator that is one of the plurality of first insulators. The device further includes a columnar portion including a third insulator provided on a side face of the stacked film, a charge storage layer provided on a side face of the third insulator, a fourth insulator provided on a side face of the charge storage layer, and a first semiconductor layer provided on a side face of the fourth insulator, the columnar portion being provided in the stacked film. The device further includes a metal layer provided on the stacked film and the columnar portion, electrically connected to the first semiconductor layer, and including one or more layers. An upper end of the columnar portion is provided at a height between an upper face and a lower face of the second insulator. A lower end of a highest layer among the one or more layers is provided at a position lower than the upper face of the second insulator.

### First Embodiment

FIG. 1 is a cross-sectional view illustrating the structure of a semiconductor device of a first embodiment.

The semiconductor device of the present embodiment includes, for example, a three-dimensional semiconductor memory. As described later, the semiconductor device of the present embodiment is manufactured by bonding an array wafer including an array chip 1 and a circuit wafer including a circuit chip 2.

The array chip 1 includes a memory cell array 11 including a plurality of memory cells, and an inter layer dielectric 12 below the memory cell array 11. The inter layer dielectric 12 is, for example, a stacked film including a silicon oxide film (SiO₂ film) and other insulators.

The circuit chip 2 is provided below the array chip 1. FIG. 1 illustrates a bonding face S between the array chip 1 and the circuit chip 2. The circuit chip 2 includes an inter layer dielectric 13 below the inter layer dielectric 12, and a substrate 14 below the inter layer dielectric 13. The inter layer dielectric 13 is a stacked film including, for example, an SiO₂ film and other insulators. The substrate 14 is, for example, a semiconductor substrate such as a silicon (Si) substrate. The substrate 14 is an example of a second substrate.

FIG. 1 illustrates an X direction and a Y direction that are parallel to the surface of the substrate 14 and orthogonal to each other, and a Z direction orthogonal to the surface of the substrate 14. The X direction, the Y direction, and the Z direction intersect one another. In the present specification, the positive Z direction is an upward direction, and the negative Z direction is a downward direction. The negative Z direction may or may not be aligned with the direction of gravity. The Z direction is an example of a first direction.

The array chip 1 includes a plurality of word lines WL, a source-side select line SGS, and a drain-side select line SGD as a plurality of electrode layers in the memory cell array 11. The source-side select line SGS is disposed above the word lines WL, and the drain-side select line SGD is disposed below the word lines WL. FIG. 1 illustrates a staircase structure portion 21 in the memory cell array 11, and a plurality of beam portions 22 provided in the staircase structure portion 21. Each word line WL is electrically connected to a word interconnect layer 24 through a contact plug 23. Each columnar portion CL penetrating through the plurality of word lines WL, the source-side select line SGS, and the drain-side select line SGD described above is electrically connected to a bit line BL through a via plug 25 and electrically connected to a source line SL. The source line SL is provided above the source-side select line SGS, and the bit line BL is provided below the drain-side select line SGD. Further details of the source line SL will be described later.

In FIG. 1, only one electrode layer that is the highest electrode layer is the source-side select line SGS, but a plurality of electrode layers on the highest side may be the source-side select line SGS. For example, three or four electrode layers on the highest side may be the source-side select line SGS. The number of electrode layers as the source-side select line SGS is optional. Similarly, in FIG. 1, only one electrode layer as the lowest electrode layer is the drain-side select line SGD, but a plurality of electrode layers on the lowest side may be the drain-side select line SGD.

The circuit chip 2 further includes a plurality of transistors 31, a plurality of contact plugs 32, an interconnect layer 33, an interconnect layer 34, an interconnect layer 35, a plurality of via plugs 36, and a plurality of metal pads 37.

Each transistor 31 includes a gate insulator 31a and a gate electrode 31b that are sequentially provided on the substrate 14, and a source region and a drain region (not illustrated) that are provided in the substrate 14. Each contact plug 32 is provided on the gate electrode 31b, source region, or drain region of the corresponding transistor 31. The interconnect layer 33 is provided on the contact plugs 32 and includes a plurality of interconnects. The interconnect layer 34 is provided on the interconnect layer 33 and includes a plurality of interconnects. The interconnect layer 35 is provided on the interconnect layer 34 and includes a plurality of interconnects. The via plugs 36 are provided on the interconnect layer 35. The metal pads 37 are provided on the via plugs 36. Each metal pad 37 is, for example, a metal layer including a copper (Cu) layer. The circuit chip 2 functions as a circuit that controls operation of the array chip 1. The circuit includes the transistors 31 and the like and electrically connected to the metal pads 37.

The array chip 1 further includes a plurality of metal pads 41, a plurality of via plugs 42, an interconnect layer 43, an interconnect layer 44, a plurality of via plugs 45, a plurality of via plugs 46, a metal pad 47, and a passivation insulator 48.

The metal pads 41 are provided on the metal pads 37. Each metal pad 41 is, for example, a metal layer including a Cu layer. The above-described circuit is electrically connected to the memory cell array 11 through the metal pads 41 and 37 and the like and controls operation of the memory cell array 11 through the metal pads 41 and 37 and the like. The via plugs 42 are provided on the metal pads 41. The interconnect layer 43 is provided on the via plugs 42 and includes a plurality of interconnects. The interconnect layer 44 is provided on the interconnect layer 43 and includes a plurality of interconnects. The above-described bit line BL is included in the interconnect layer 44. The via plugs 45 are provided on the interconnect layer 44. The via plugs 46 are provided on the via plugs 45.

The metal pad 47 is provided on the via plugs 46 and the inter layer dielectric 12. The metal pad 47 is, for example, a metal layer including a Cu layer and functions as an external connection pad (bonding pad) of the semiconductor device of the present embodiment. The passivation insulator 48 is provided on the metal pad 47 and the inter layer dielectric 12. The passivation insulator 48 is, for example, a stacked film including an SiO₂ film and a silicon nitride film (SiN film) and has an opening P through which the upper face of a metal pad 47 is exposed. The metal pad 47 is connectable to a mounting substrate or other devices through the opening P by a bonding wire, a soldering ball, a metal bump, or the like.

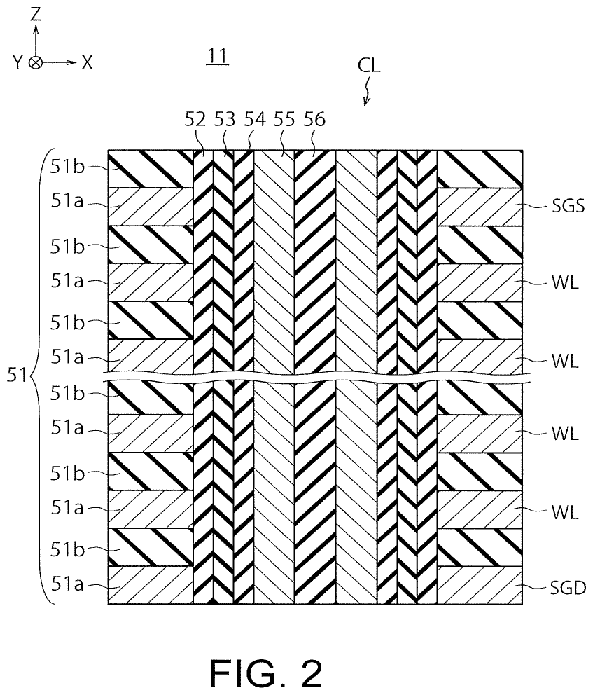

FIG. 2 is an enlarged cross-sectional view illustrating the structure of the semiconductor device of the first embodiment.

FIG. 2 illustrates the memory cell array 11 in FIG. 1. The memory cell array 11 includes a stacked film 51 including a plurality of electrode layers 51a and a plurality of insulators 51b that are alternately stacked in the Z direction. Each electrode layers 51a functions as, for example, the word lines WL, the source-side select line SGS, or the drain-side select line SGD. In FIG. 2, the highest electrode layer 51a is the source-side select line SGS, the lowest electrode layer 51a is the drain-side select line SGD, and other electrode layers 51a are the word lines WL. Each electrode layer 51a is, for example, a metal layer including a tungsten (W) layer. Each insulator 51b is, for example, an SiO₂ film. Each insulator 51b is an example of a first insulator.

FIG. 2 further illustrates one of the plurality of columnar portions CL in FIG. 1. Each columnar portion CL is provided in the stacked film 51 and has a columnar shape extending in the Z direction. Each columnar portion CL includes a block insulator 52 provided on the side face of the stacked film 51, a charge storage layer 53 provided on the side face of the block insulator 52, a tunnel insulator 54 provided on the side face of the charge storage layer 53, a channel semiconductor layer 55 provided on the side face of the tunnel insulator 54, and a core insulator 56 provided on the side face of the channel semiconductor layer 55. Each columnar portion CL constitutes a cell transistor (memory cell) together with the word lines WL, constitutes a source-side selection transistor together with the source-side select line SGS, and constitutes a drain-side selection transistor together with the drain-side select line SGD.

The block insulator 52 is, for example, an SiO₂ film. The charge storage layer 53 can store signal charge of the three-dimensional semiconductor memory. The charge storage layer 53 is, for example, an insulator such as an SiN film. The charge storage layer 53 may be a semiconductor layer such as a polysilicon layer. The tunnel insulator 54 is, for example, an SiO₂ film or a silicon oxynitride film (SiON film). The channel semiconductor layer 55 functions as a channel of the three-dimensional semiconductor memory. The channel semiconductor layer 55 is, for example, a polysilicon layer. The core insulator 56 is, for example, an SiO₂ film. The block insulator 52, the tunnel insulator 54, and the core insulator 56 are examples of third, fourth, and fifth insulators, respectively. The channel semiconductor layer 55 is an example of a first semiconductor layer.

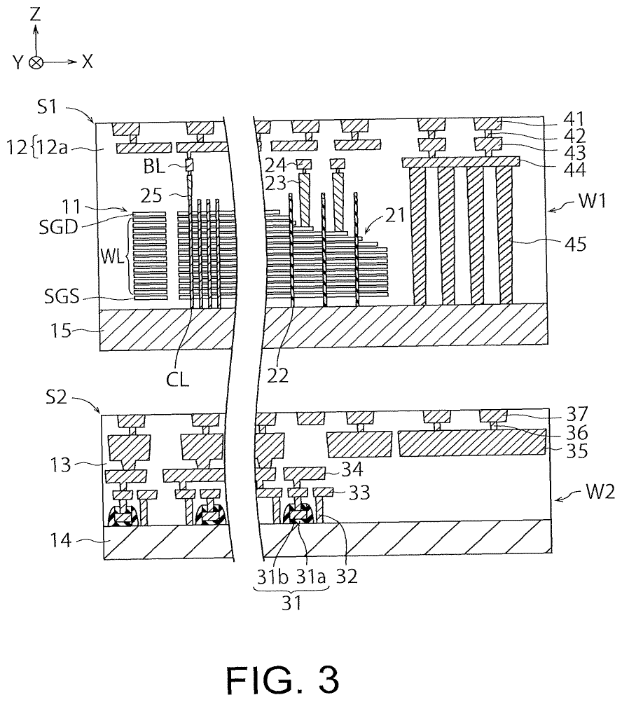

FIGS. 3 to 6 are cross-sectional views illustrating a method of manufacturing the semiconductor device of the first embodiment.

FIG. 3 illustrates an array wafer W1 including a plurality of array chips 1, and a circuit wafer W2 including a plurality of circuit chips 2. The orientation of the array wafer W1 in FIG. 3 is opposite the orientation of the array chip 1 in FIG. 1. In the present embodiment, a semiconductor device is manufactured by bonding the array wafer W1 and the circuit wafer W2. FIG. 3 illustrates the array wafer W1, the orientation of which is yet to be inverted for bonding, and FIG. 1 illustrates the array chip 1, the orientation of which is inverted for bonding and that is bonded and diced.

FIG. 3 further illustrates an upper face S1 of the array wafer W1 and an upper face S2 of the circuit wafer W2. The array wafer W1 includes a substrate 15 below the memory cell array 11. The substrate 15 is, for example, a semiconductor substrate such as an Si substrate. The substrate 15 is an example of a first substrate.

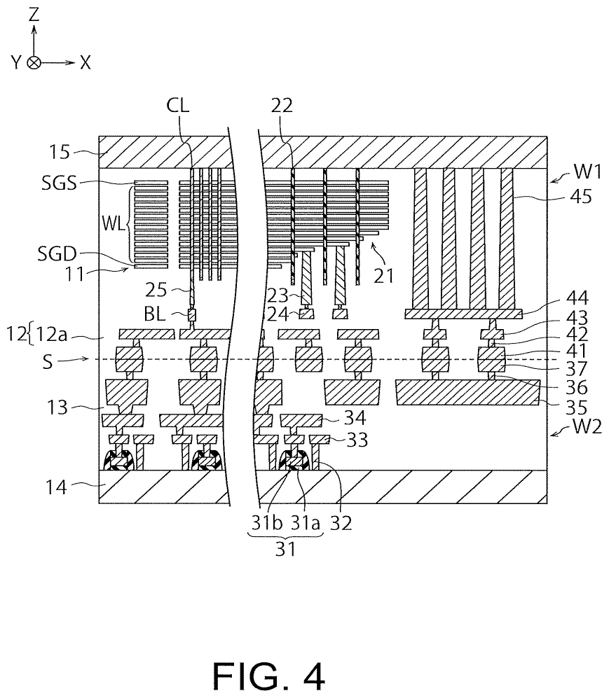

In the present embodiment, first, the memory cell array 11, an inter layer dielectric 12a (portion of the inter layer dielectric 12), the staircase structure portion 21, the metal pads 41, the via plugs 45, and the like are formed on the substrate 15 of the array wafer W1, and the inter layer dielectric 13, the transistors 31, the metal pads 37, and the like are formed on the substrate 14 of the circuit wafer W2 as illustrated in FIG. 3. Subsequently, as illustrated in FIG. 4, the array wafer W1 and the circuit wafer W2 are bonded to each other by mechanical pressure such that the upper face S1 and the upper face S2 face each other. Accordingly, the inter layer dielectric 12a and the inter layer dielectric 13 are bonded to each other. Subsequently, the array wafer W1 and the circuit wafer W2 are annealed. Accordingly, the metal pads 41 and the metal pads 37 are joined together. In this manner, the substrate 15 and the substrate 14 are bonded to sandwich the inter layer dielectrics 12a and 13.

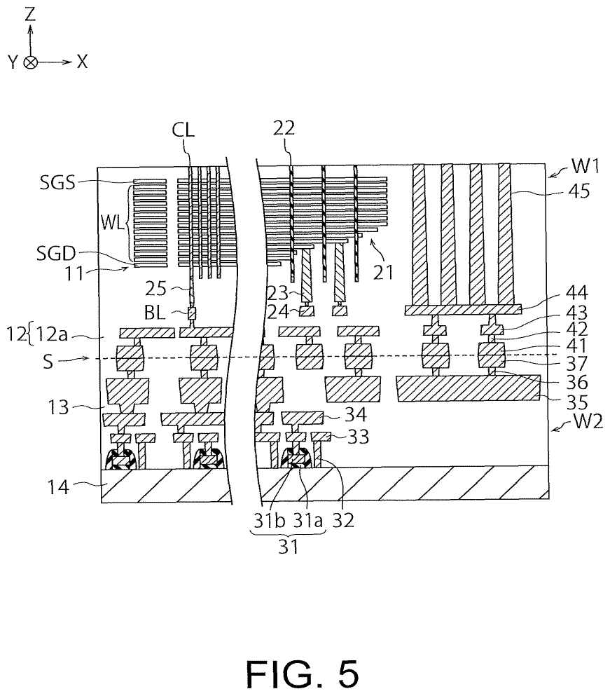

Subsequently, the substrate 15 is removed by chemical mechanical polishing (CMP) or wet etching, and the substrate 14 is thinned by CMP or wet etching (FIG. 5). Accordingly, the inter layer dielectric 12a, the columnar portions CL, the beam portions 22, the via plugs 45, and the like are exposed.

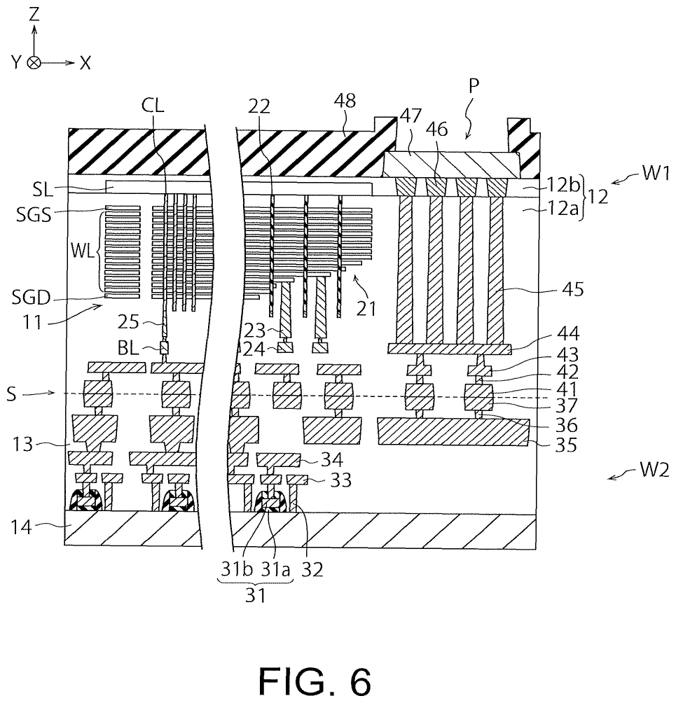

Subsequently, the source line SL is formed on the inter layer dielectric 12a, the columnar portions CL, and the beam portions 22, and an inter layer dielectric 12b (rest of the inter layer dielectric 12) is formed on the inter layer dielectric 12a with the source line SL interposed therebetween (FIG. 6). Subsequently, the via plugs 46 are formed on the via plugs 45 in the inter layer dielectric 12b, and the metal pad 47 is formed on the inter layer dielectric 12b and the via plugs 46 (FIG. 6). Subsequently, the passivation insulator 48 is formed on the inter layer dielectric 12b and the metal pad 47, and the opening P is formed in the passivation insulator 48 (FIG. 6).

Thereafter, the array wafer W1 and the circuit wafer W2 are disconnected into a plurality of chips. In this manner, the semiconductor device in FIG. 1 is manufactured.

Note that although FIG. 1 illustrates the boundary face between the inter layer dielectric 12 and the inter layer dielectric 13 and the boundary face between each metal pad 41 and the corresponding metal pad 37, these boundary faces are typically not observed after the above-described annealing. However, the positions of the boundary faces can be estimated by detecting, for example, the tilt of the side face of both the metal pad 41 and the metal pad 37, and positional shift between the side face of the metal pad 41 and the side face of the metal pad 37.

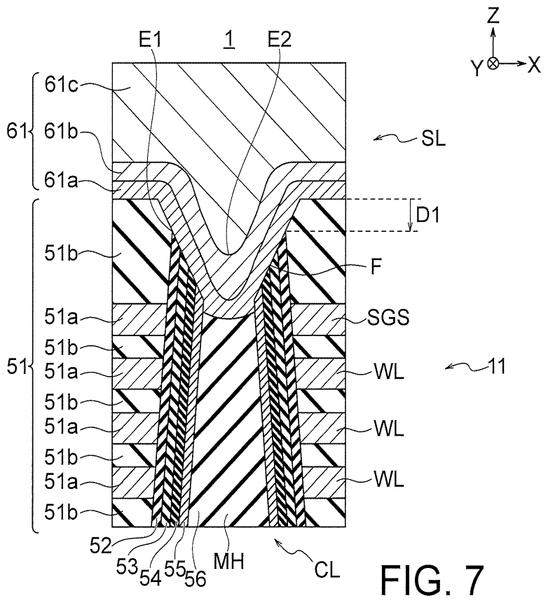

FIG. 7 is a cross-sectional view illustrating the structure of the semiconductor device of the first embodiment.

As in FIG. 2, FIG. 7 illustrates a columnar portion CL in the stacked film 51. The columnar portion CL is formed in a memory hole MH formed in the stacked film 51. FIG. 7 further illustrates an interconnect layer 61.

The interconnect layer 61 is formed on the stacked film 51 and the columnar portion CL. The interconnect layer 61 contacts the channel semiconductor layer 55 and is electrically connected to the channel semiconductor layer 55. The interconnect layer 61 includes a plurality of interconnects. FIG. 7 illustrates the source line SL as one of the interconnects. The interconnect layer 61 is also referred to as a source layer. The interconnect layer 61 includes a lower barrier metal layer 61a, an upper barrier metal layer 61b, and an interconnect material layer 61c. The lower barrier metal layer 61a, the upper barrier metal layer 61b, and the interconnect material layer 61c are examples of one or more layers in a metal layer.

The lower barrier metal layer 61a is formed on the stacked film 51 and the columnar portion CL. The upper barrier metal layer 61b is formed on the lower barrier metal layer 61a. The interconnect material layer 61c is formed on the upper barrier metal layer 61b. The lower barrier metal layer 61a is, for example, a titanium (Ti) layer. The upper barrier metal layer 61b is, for example, a titanium nitride film (TiN film). The interconnect material layer 61c is, for example, a metal layer such as a W layer. The interconnect material layer 61c of the present embodiment is a main layer in the interconnect layer 61 and occupies a maximum volume in the interconnect layer 61. In the present embodiment, the interconnect layer 61 includes the three layers of the lower barrier metal layer 61a, the upper barrier metal layer 61b, and the interconnect material layer 61c, and the interconnect material layer 61c is the highest layer among the three layers.

In FIG. 7, the highest electrode layer 51a among the plurality of electrode layers 51a in the stacked film 51 is the source-side select line SGS. In FIG. 7, the film thickness of the highest insulator 51b among the plurality of insulators 51b in the stacked film 51 is larger than the film thickness of any other insulators 51b. The highest insulator 51b is also referred to as an SGS insulator. The highest insulator 51b is an example of a second insulator. The highest insulator 51b is the top layer of the stacked film 51.

FIG. 7 further illustrates an upper face F of the columnar portion CL, an upper end E1 of the columnar portion CL, and a lower end E2 of the interconnect material layer 61c.

In FIG. 7, the upper face F of the columnar portion CL includes the upper face of the block insulator 52, the upper face of the charge storage layer 53, the upper face of the tunnel insulator 54, and the upper face of the channel semiconductor layer 55. The upper face F of the columnar portion CL of the present embodiment is not parallel but tilted to an XY plane.

The upper end E1 of the columnar portion CL is provided at a height between the upper and lower faces of the highest insulator 51b. In other words, the upper end E1 of the columnar portion CL is provided at a position lower than the upper face of the highest insulator 51b and provided at a position higher than the lower face of the highest insulator 51b, and as a result, provided in the highest insulator 51b. FIG. 7 illustrates a distance D1 between the upper end E1 of the columnar portion CL and the upper face of the highest insulator 51b. In FIG. 7, the upper end E1 of the columnar portion CL is the upper end of the upper face F of the columnar portion CL and formed of the block insulator 52. In FIG. 7, the entire upper face F of the columnar portion CL is provided in the highest insulator 51b.

The lower end E2 of the interconnect material layer 61c is provided at a position lower than the upper face of the highest insulator 51b. The lower end E2 of the interconnect material layer 61c is provided at a position higher than the lower face of the highest insulator 51b. The lower end E2 of the interconnect material layer 61c is provided at a position lower than the upper end E1 of the columnar portion CL in FIG. 7, but may be provided at a position higher than the upper end E1 of the columnar portion CL instead.

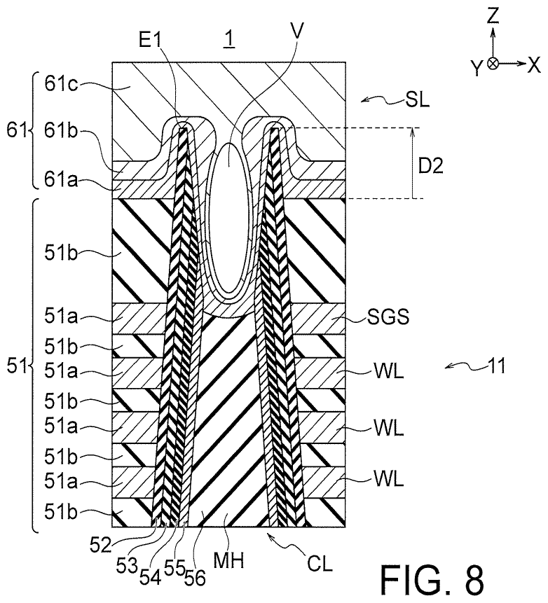

FIG. 8 is a cross-sectional view illustrating the structure of a semiconductor device of a comparative example of the first embodiment.

The semiconductor device of the present comparative example (FIG. 8) has the same structure as the semiconductor device of the first embodiment (FIG. 7). However, the upper end E1 of the columnar portion CL of the present comparative example is provided at a position higher than the upper face of the highest insulator 51b, and as a result, and protrudes in the positive Z direction from the upper face of the stacked film 51. FIG. 8 illustrates a distance D2 between the upper end E1 of the columnar portion CL of the present comparative example and the upper face of the highest insulator 51b. FIG. 8 further illustrates a void V formed in the interconnect layer 61 near the interface between the columnar portion CL and the interconnect layer 61.

The interconnect layer 61 of the present comparative example is formed on the stacked film 51 and the columnar portion CL through the process illustrated in FIG. 6. In this case, a portion of the interconnect layer 61 is embedded in a concave portion formed of the stacked film 51 and the columnar portion CL. In the present comparative example, since the upper end E1 of the columnar portion CL protrudes in the positive Z direction from the upper face of the stacked film 51, the concave portion has a high aspect ratio. As a result, the interconnect layer 61 is unlikely to enter the concave portion, and the void V is generated. The void V can cause a connection defect between the columnar portion CL and the interconnect layer 61.

Similarly, the interconnect layer 61 of the first embodiment is formed on the stacked film 51 and the columnar portion CL through the process illustrated in FIG. 6. In this case, a portion of the interconnect layer 61 is embedded in a concave portion formed of the stacked film 51 and the columnar portion CL. In the present embodiment, since the upper end E1 of the columnar portion CL does not protrude in the positive Z direction from the upper face of the stacked film 51, the concave portion has a low aspect ratio. Thus, the present embodiment makes it possible for the interconnect layer 61 to enter the concave portion and the generation of the void V can be prevented. In FIG. 8, the lower barrier metal layer 61a, the upper barrier metal layer 61b, and the interconnect material layer 61c sufficiently enter the concave portion.

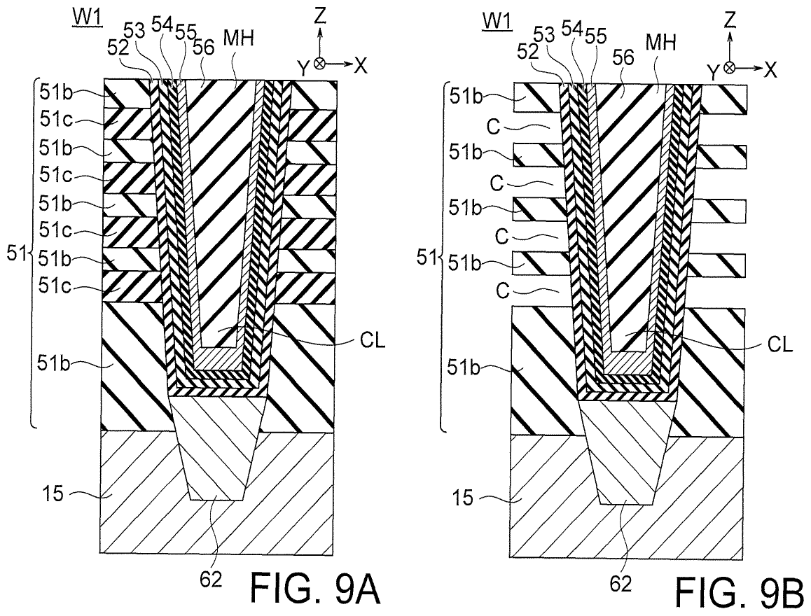

FIGS. 9A to 12B are cross-sectional views illustrating a method of manufacturing the semiconductor device of the first embodiment. FIGS. 9A to 12B illustrate an example method of manufacturing the semiconductor device illustrated in FIGS. 3 to 6.

First, the stacked film 51 including a plurality of sacrifice layers 51c and the plurality of insulators 51b alternately in the Z direction is formed above the substrate 15 of the array wafer W1 (FIG. 9A). The stacked film 51 is formed by alternately stacking a plurality of sacrifice layers 51c and a plurality of insulators 51b on the substrate 15. Each sacrifice layer 51c is, for example, an SiN film. Each sacrifice layer 51c is an example of a first layer.

Subsequently, a plurality of memory holes MH are formed in the stacked film 51 and the substrate 15 by lithography and reactive ion etching (RIE) (FIG. 9A). FIG. 9A illustrates one of the memory holes MH. Each memory hole MH is formed to have a columnar shape extending in the Z direction and to penetrate the stacked film 51 in the Z direction. Each memory hole MH is an example of a first opening.

Subsequently, a sacrifice layer 62 is formed on a substrate 15 in each memory hole MH (FIG. 9A). The sacrifice layer 62 is, for example, a semiconductor layer such as an Si layer. The sacrifice layer 62 of the present embodiment is formed by epitaxial growth from the substrate 15. The upper face of the sacrifice layer 62 is formed, for example, at a height between the upper and lower faces of the lowest insulator 51b in FIG. 9A. The lowest insulator 51b in FIG. 9A corresponds to the above-described SGS insulator. The sacrifice layer 62 is an example of a second layer.

Subsequently, the block insulator 52, the charge storage layer 53, the tunnel insulator 54, the channel semiconductor layer 55, and the core insulator 56 are sequentially formed in each memory hole MH (FIG. 9A). As a result, the block insulator 52, the charge storage layer 53, the tunnel insulator 54, the channel semiconductor layer 55, and the core insulator 56 are sequentially formed on the side face of the stacked film 51 and the upper face of the sacrifice layer 62. In this manner, a columnar portion CL is formed on the sacrifice layer 62 in each memory hole MH.

Subsequently, a plurality of slits (not illustrated) are formed in the stacked film 51 and the substrate 15, and the sacrifice layers 51c are removed from the stacked film 51 through the slits by wet etching (FIG. 9B). As a result, a plurality of concave portions C are formed in the stacked film 51.

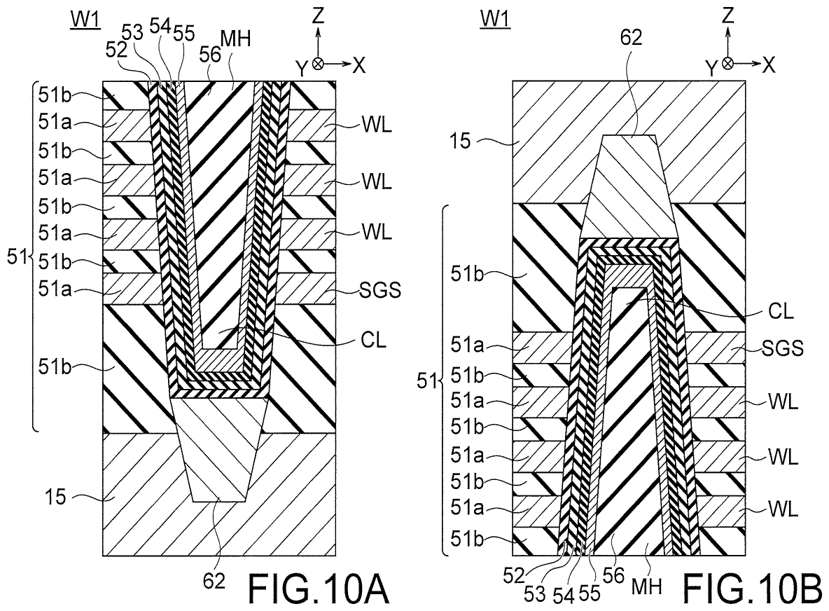

Subsequently, the electrode layers 51a are formed in the concave portions C through the slits (FIG. 10A). In this manner, a plurality of sacrifice layers 51c in the stacked film 51 are replaced with a plurality of electrode layers 51a (replacement process). The lowest electrode layer 51a in FIG. 10A corresponds to the source-side select line SGS.

FIG. 10A illustrates the array wafer W1 before being bonded to the circuit wafer W2, whereas FIG. 10B illustrates the array wafer W1 after being bonded to the circuit wafer W2.

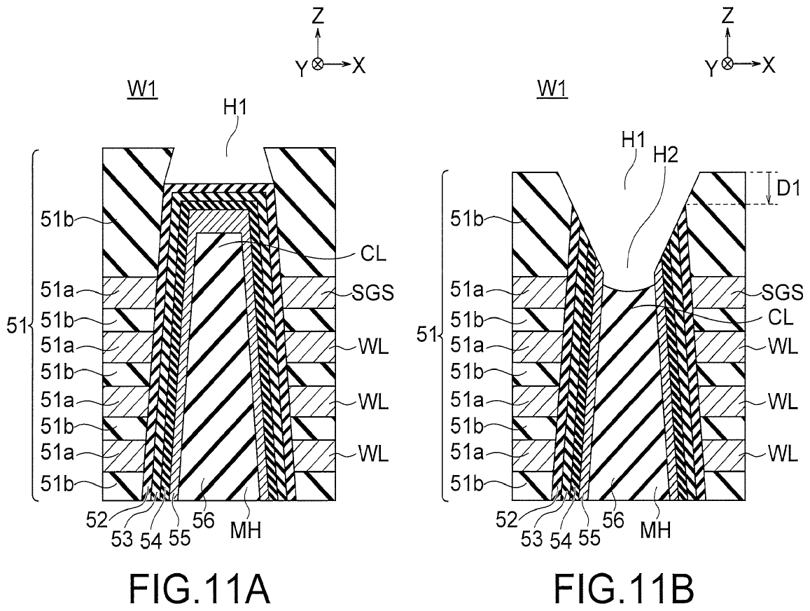

Subsequently, the substrate 15 is removed by wet etching (FIG. 11A). In a case where the substrate 15 and the sacrifice layer 62 are a semiconductor substrate and a semiconductor layer, respectively, the sacrifice layer 62 is removed as well by the wet etching. As a result, a concave portion H1 is formed in a region from which the sacrifice layer 62 is removed, and the block insulator 52 of each columnar portion CL is exposed in the concave portion H1. The concave portion H1 is formed on each columnar portion CL in the stacked film 51. The concave portion H1 is formed, for example, in the highest insulator 51b in FIG. 11A. The highest insulator 51b in FIG. 11A corresponds to the above-described SGS insulator. The concave portion H1 is an example of a second opening.

Subsequently, a portion of the block insulator 52, the charge storage layer 53, the tunnel insulator 54, the channel semiconductor layer 55, and the core insulator 56 of each columnar portion CL is removed by etching back from the concave portion H1 (FIG. 11B). As a result, a concave portion H2 is formed in each columnar portion CL, and then each columnar portion CL is processed into a shape illustrated in FIG. 11B, and the block insulator 52, the charge storage layer 53, the tunnel insulator 54, the channel semiconductor layer 55, and the core insulator 56 of each columnar portion CL are exposed in the concave portions H1 and H2.

The shape of the columnar portion CL illustrated in FIG. 11B is the same as the shape of the columnar portion CL illustrated in FIG. 7. Accordingly, the upper end of the columnar portion CL illustrated in FIG. 11B is positioned at a height between the upper and lower faces of the highest insulator 51b. As in FIG. 7, FIG. 11B illustrates the distance D1 between the upper end of the columnar portion CL and the upper face of the highest insulator 51b.

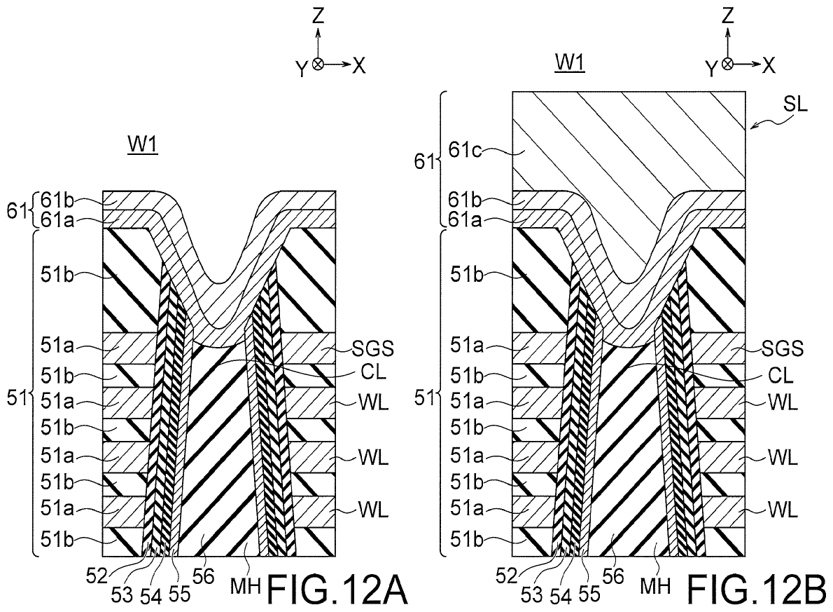

Subsequently, the lower barrier metal layer 61a is formed on the stacked film 51 and each columnar portion CL, and the upper barrier metal layer 61b is formed on the lower barrier metal layer 61a (FIG. 12A). As a result, the lower barrier metal layer 61a and the upper barrier metal layer 61b are sequentially formed on the block insulator 52, the charge storage layer 53, the tunnel insulator 54, the channel semiconductor layer 55, and the core insulator 56.

Subsequently, the interconnect material layer 61c is formed on the upper barrier metal layer 61b (FIG. 12B). As a result, the interconnect layer 61 is formed on each columnar portion CL and electrically connected to the channel semiconductor layer 55 of each columnar portion CL. The interconnect layer 61 is formed by, for example, sequentially forming the lower barrier metal layer 61a, the upper barrier metal layer 61b, and the interconnect material layer 61c on the stacked film 51 and processing the lower barrier metal layer 61a, the upper barrier metal layer 61b, and the interconnect material layer 61c by etching. In FIG. 12B, the interconnect layer 61 (source line SL) contacts the channel semiconductor layer 55. In FIG. 12B, the lower end of the interconnect material layer 61c is positioned at a position lower than the upper face of the highest insulator 51b.

In the present embodiment, since the upper end of the columnar portion CL does not protrude in the positive Z direction from the upper face of the stacked film 51, the concave portions H1 and H2 have low aspect ratios. Thus, the present embodiment makes it possible for the interconnect layer 61 to enter the concave portions H1 and H2 and the generation of the void V can be prevented. In FIGS. 12A and 12B, the lower barrier metal layer 61a, the upper barrier metal layer 61b, and the interconnect material layer 61c sufficiently enter the concave portions H1 and H2.

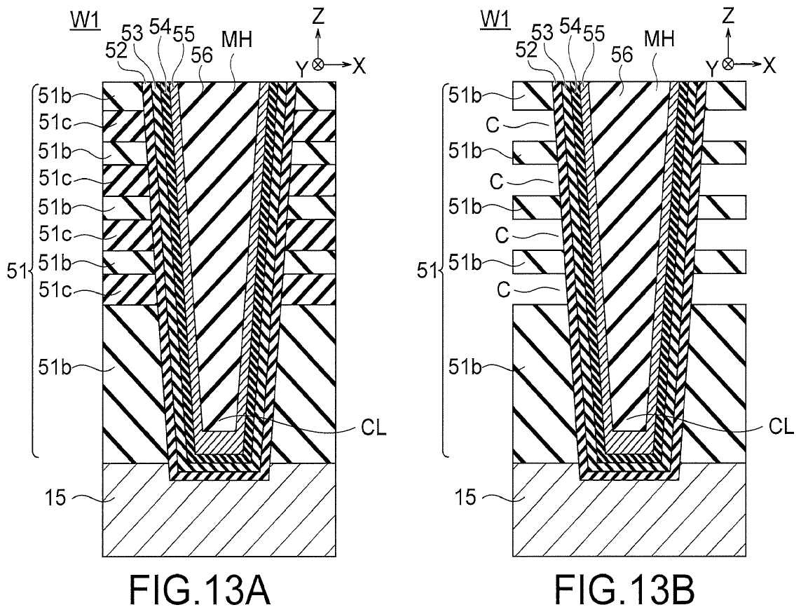

FIGS. 13A to 16B are cross-sectional views illustrating a method of manufacturing a semiconductor device of the comparative example of the first embodiment.

First, the stacked film 51 including a plurality of sacrifice layers 51c and a plurality of insulators 51b alternately in the Z direction is formed above the substrate 15 of the array wafer W1 (FIG. 13A). Subsequently, a plurality of memory holes MH are formed in the stacked film 51 and the substrate 15 (FIG. 13A). FIG. 13A illustrates one of the memory holes MH. Subsequently, the block insulator 52, the charge storage layer 53, the tunnel insulator 54, the channel semiconductor layer 55, and the core insulator 56 are sequentially formed in each memory hole MH (FIG. 13A). As a result, a columnar portion CL is formed in each memory hole MH. Note that the sacrifice layer 62 is not formed through the process in FIG. 13A.

Subsequently, the sacrifice layers 51c are removed from the stacked film 51 (FIG. 13B). As a result, a plurality of concave portions C are formed in the stacked film 51.

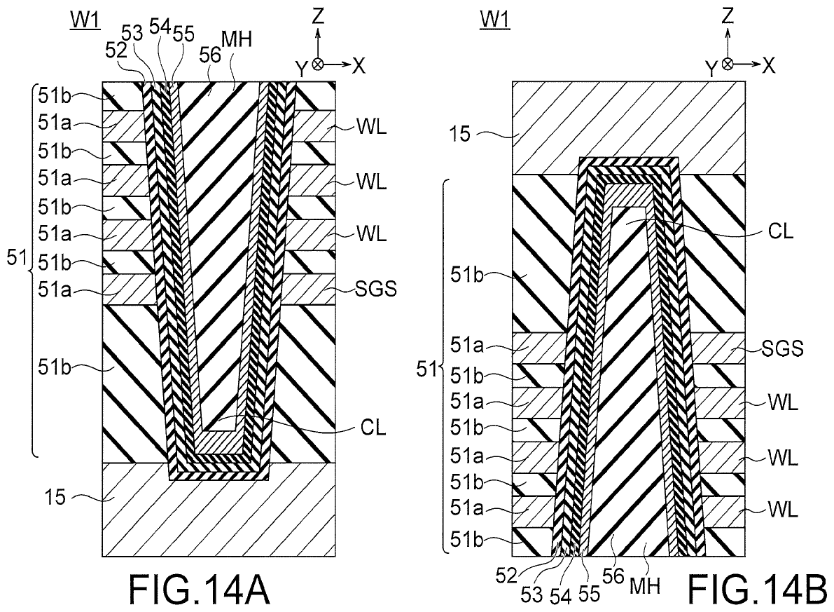

Subsequently, the electrode layers 51a are formed in the concave portions C (FIG. 14A). In this manner, a plurality of sacrifice layers 51c in the stacked film 51 are replaced with a plurality of electrode layers 51a.

FIG. 14A illustrates the array wafer W1 before being bonded to the circuit wafer W2, whereas FIG. 14B illustrates the array wafer W1 after being bonded to the circuit wafer W2.

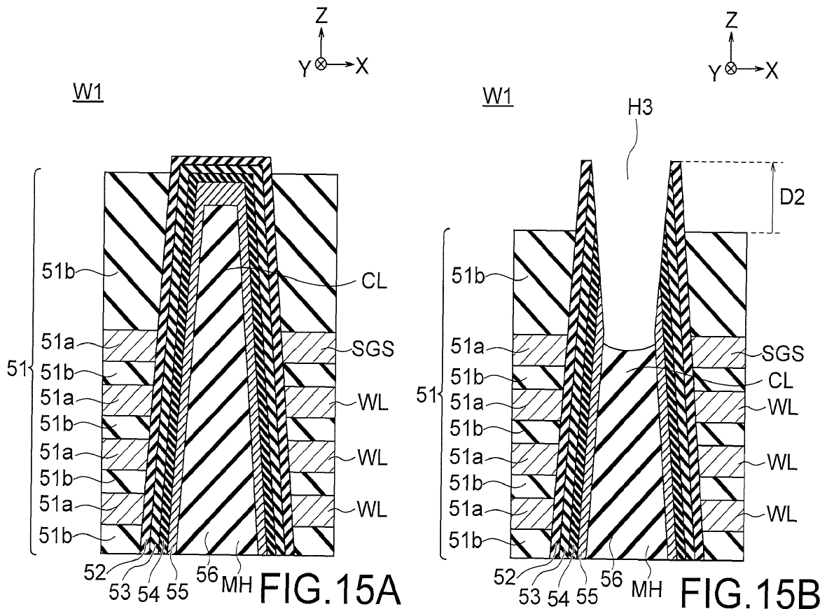

Subsequently, the substrate 15 is removed (FIG. 15A). As a result, the block insulator 52 of each columnar portion CL is exposed.

Subsequently, a portion of the block insulator 52, the charge storage layer 53, the tunnel insulator 54, the channel semiconductor layer 55, and the core insulator 56 of each columnar portion CL is removed by etching back (FIG. 15B). As a result, a concave portion H3 is formed in each columnar portion CL, and then the columnar portion CL is processed into a shape illustrated in FIG. 15B, and the block insulator 52, the charge storage layer 53, the tunnel insulator 54, the channel semiconductor layer 55, and the core insulator 56 of each columnar portion CL are exposed in the concave portion H3.

The shape of the columnar portion CL illustrated in FIG. 15B is the same as the shape of the columnar portion CL illustrated in FIG. 8. Thus, the upper end of the columnar portion CL illustrated in FIG. 15B is positioned at a position higher than the upper face of the highest insulator 51b. As in FIG. 8, FIG. 15B illustrates the distance D2 between the upper end of the columnar portion CL and the upper face of the highest insulator 51b.

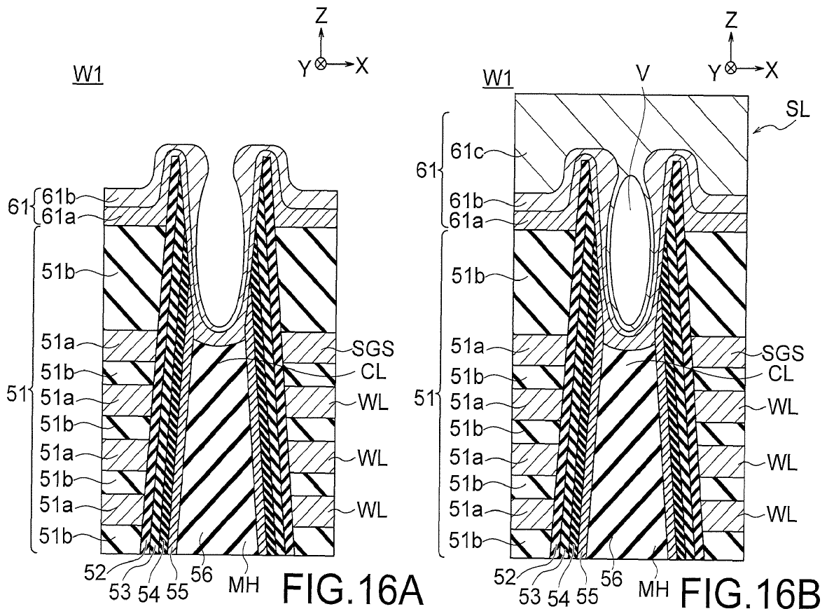

Subsequently, the lower barrier metal layer 61a is formed on the stacked film 51 and each columnar portion CL, and the upper barrier metal layer 61b is formed on the lower barrier metal layer 61a (FIG. 16A).

Subsequently, the interconnect material layer 61c is formed on the upper barrier metal layer 61b (FIG. 16B). As a result, the interconnect layer 61 is formed on each columnar portion CL.

In the present comparative example, since the upper end of the columnar portion CL protrudes in the positive Z direction from the upper face of the stacked film 51, the concave portion H3 has a high aspect ratio. As a result, the interconnect layer 61 is unlikely to enter the concave portion H3, and the void V is generated. The void V can cause a connection defect between the columnar portion CL and the interconnect layer 61.

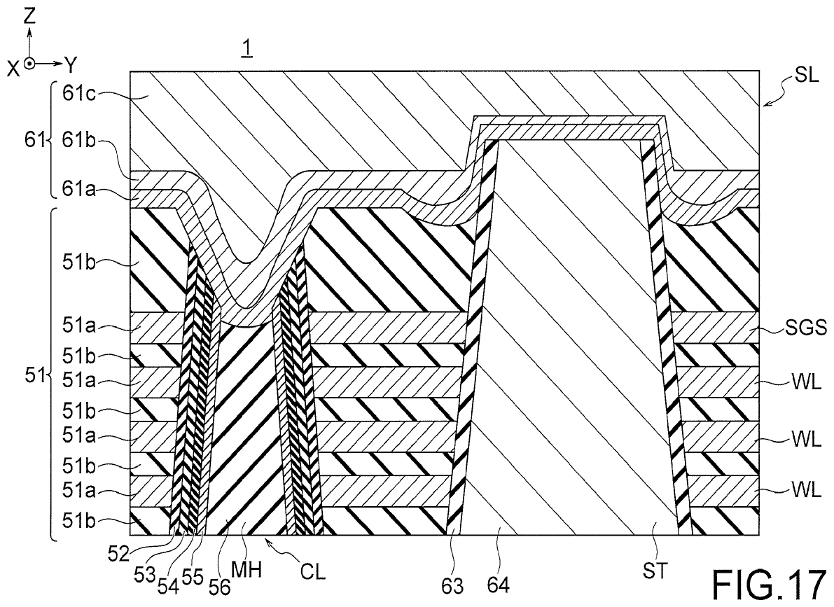

FIG. 17 is a cross-sectional view illustrating the structure of the semiconductor device of the first embodiment. FIG. 17 illustrates a YZ section of the semiconductor device of the present embodiment.

The semiconductor device of the present embodiment includes a plurality of slits ST formed in the stacked film 51. FIG. 17 illustrates one of the slits ST. Each slit ST is formed to have a plate shape extending in the Z and X directions and to penetrate through the stacked film 51 in the Z direction. The slits ST are used in the processes illustrated in FIGS. 9B and 10A as described above.

The semiconductor device of the present embodiment further includes an insulator 63 and an interconnect layer 64 that are sequentially formed in each slit ST. The insulator 63 is, for example, an SiO₂ film. The interconnect layer 64 is, for example, a polysilicon layer or a metal layer. The insulator 63 and the interconnect layer 64 are formed, for example, after the replacement process. In FIG. 17, the interconnect layer 61 is formed on a columnar portion CL and the interconnect layer 64.

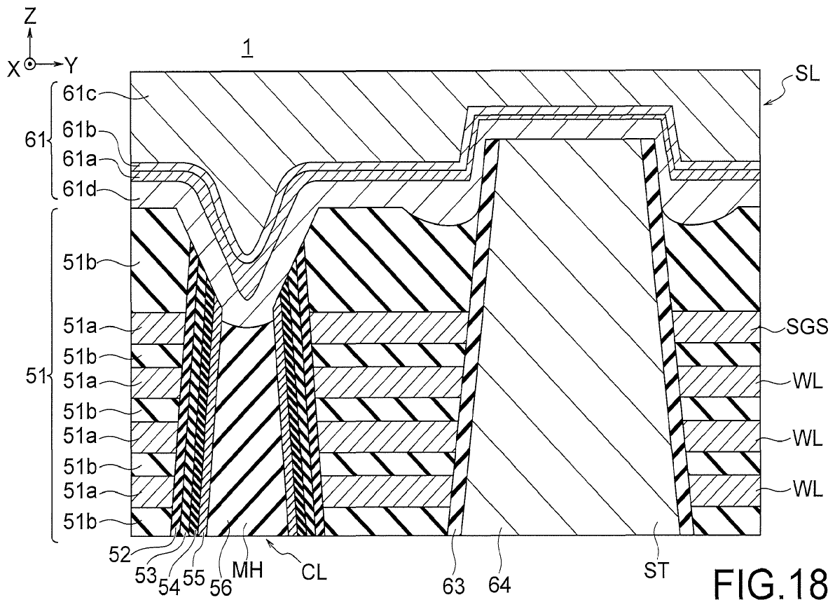

FIG. 18 is a cross-sectional view illustrating the structure of a semiconductor device of a modification of the first embodiment. FIG. 18 illustrates a YZ section of the semiconductor device of the present modification.

The semiconductor device of the present modification (FIG. 18) has the same structure as the semiconductor device of the first embodiment (FIG. 17). However, the interconnect layer 61 of the present modification includes a semiconductor layer 61d below the lower barrier metal layer 61a. The semiconductor layer 61d is, for example, a polysilicon layer. The semiconductor layer 61d is an example of a second semiconductor layer. The interconnect layer 61 of the present modification is formed by sequentially forming the semiconductor layer 61d, the lower barrier metal layer 61a, the upper barrier metal layer 61b, and the interconnect material layer 61c on the stacked film 51 and each columnar portion CL through the processes illustrated in FIGS. 12A and 12B. In this manner, the interconnect layer 61 may include both a semiconductor layer (61d) and a metal layer (61a to 61c).

As described above, the upper end E1 of the columnar portion CL of the present embodiment is provided at a height between the upper and lower faces of the highest insulator 51b (FIG. 7). In addition, the lower end E2 of the interconnect material layer 61c of the present embodiment is provided at a position lower than the upper face of the highest insulator 51b (FIG. 7). Thus, the present embodiment makes it possible to form a suitable interconnect layer 61 on the channel semiconductor layer 55. For example, the present embodiment makes it possible for the interconnect layer 61 to enter the concave portions H1 and H2 and the generation of the void V can be prevented.

### Second Embodiment

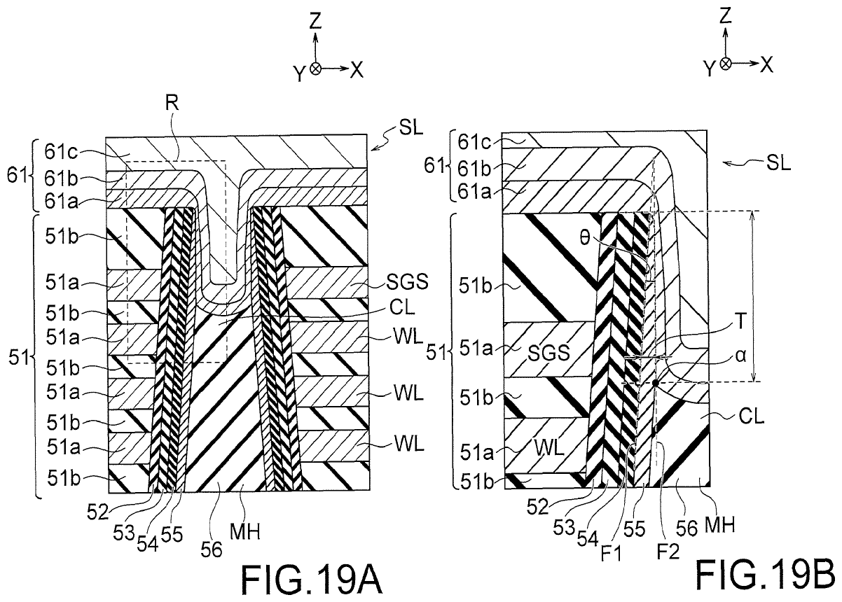

FIGS. 19A and 19B are cross-sectional views illustrating the structure of a semiconductor device of a second embodiment.

As in FIGS. 7 and 8, FIG. 19A illustrates a columnar portion CL in the stacked film 51. Although the upper end of the columnar portion CL illustrated in FIG. 7 is provided at a position lower than the upper face of the highest insulator 51b and the upper end of the columnar portion CL illustrated in FIG. 8 is provided at a position higher than the upper face of the highest insulator 51b, the upper end of the columnar portion CL of the present embodiment illustrated in FIG. 19A is provided at the same height as the upper face of the highest insulator 51b. However, the upper end of the columnar portion CL of the present embodiment may be provided at a position lower than the upper face of the highest insulator 51b as illustrated in FIG. 7 or may be provided at a position higher than the upper face of the highest insulator 51b as illustrated in FIG. 8.

FIG. 19B enlarges a region R illustrated in FIG. 19A. The upper end of the columnar portion CL of the present embodiment is the upper faces of the block insulator 52, the charge storage layer 53, and the tunnel insulator 54. FIG. 19B illustrates a triple point α where the channel semiconductor layer 55, the core insulator 56, and the interconnect layer 61 contact one another. The upper end of the columnar portion CL of the present embodiment is provided at a position higher than the triple point α. For example, the upper end of the columnar portion CL of the present embodiment is provided at a position higher than the triple point α by 10 nm or more.

In FIG. 19B, the thickness of the channel semiconductor layer 55 at a position higher than the triple point α is smaller than the thickness of the channel semiconductor layer 55 at a position lower than the triple point α. FIG. 19B illustrates a straight line F1 along the outer peripheral face of the channel semiconductor layer 55 at a position higher than the triple point α and a straight line F2 along the inner peripheral face of the channel semiconductor layer 55 at a position higher than the triple point α. FIG. 19B further illustrates the thickness T of the channel semiconductor layer 55 at a position higher than the triple point α. The thickness T corresponds to the distance between the straight lines F1 and F2.

In FIG. 19B, the thickness of the channel semiconductor layer 55 at a position lower than the triple point α is constant, and the thickness T of the channel semiconductor layer 55 at a position higher than the triple point α decreases with the height from the triple point α. For example, the thickness T at a position higher than the triple point α by 5 nm is smaller than the thickness T at the triple point α. In addition, the thickness T at the position higher than the triple point α by 10 nm is smaller than the thickness T at the position higher than the triple point α by 5 nm. When this relation is generalized, the thickness T at a position higher than the triple point α by X′ nm is smaller than the thickness T at a position higher than the triple point α by X nm (X′>X). Thus, in FIG. 19B, the straight lines F1 and F2 intersect each other at a position higher than the triple point α. FIG. 19B further illustrates an angle θ between the straight lines F1 and F2. At a position higher than the triple point α in the present embodiment, the inner peripheral face of the channel semiconductor layer 55 is tapered relative to the outer peripheral face of the channel semiconductor layer 55.

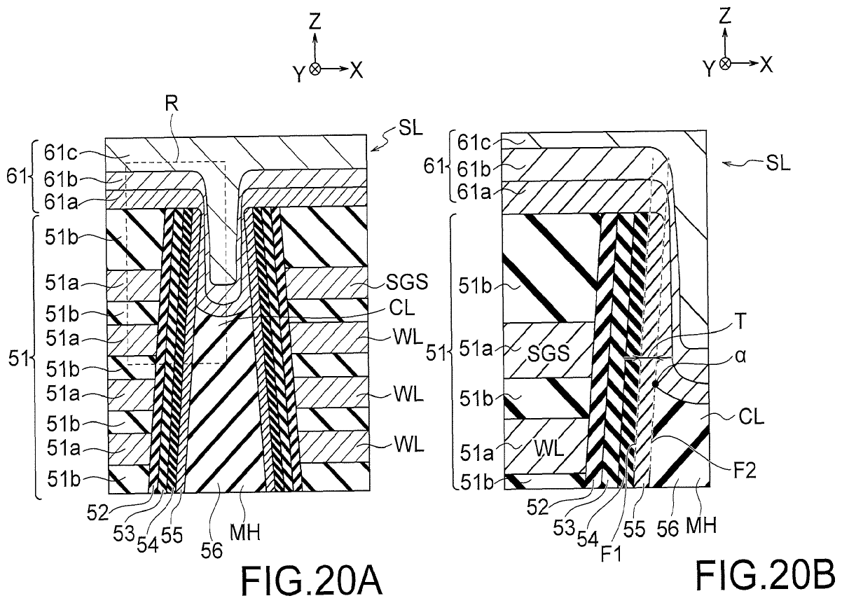

FIGS. 20A and 20B are cross-sectional views illustrating the structure of a semiconductor device of a comparative example of the second embodiment.

As in FIG. 19A, FIG. 20A illustrates a columnar portion CL in the stacked film 51. FIG. 20B enlarges a region R illustrated in FIG. 20A. In FIG. 20B the thickness of the channel semiconductor layer 55 at a position lower than the triple point α is constant, and the thickness T of the channel semiconductor layer 55 at a position higher than the triple point α is constant as well.

Problems of the comparative example of the second embodiment will be described below.

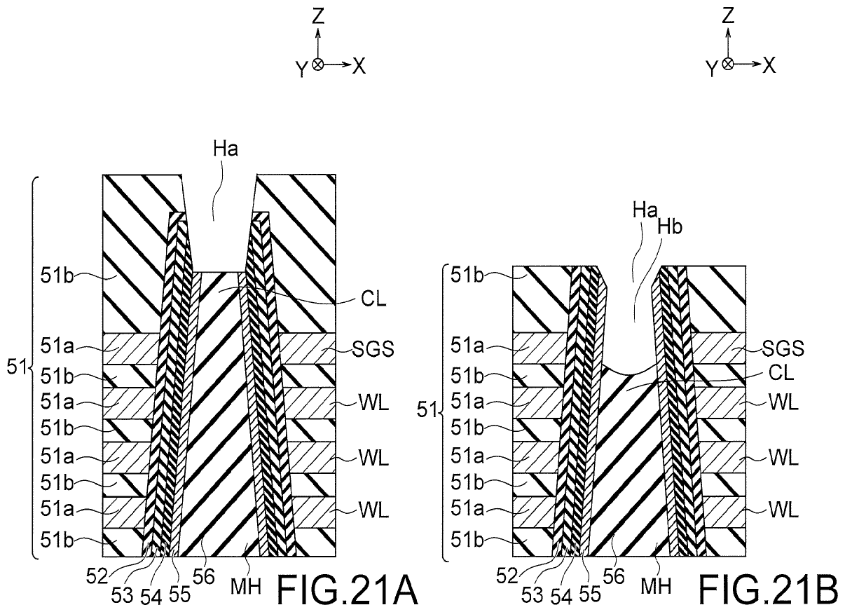

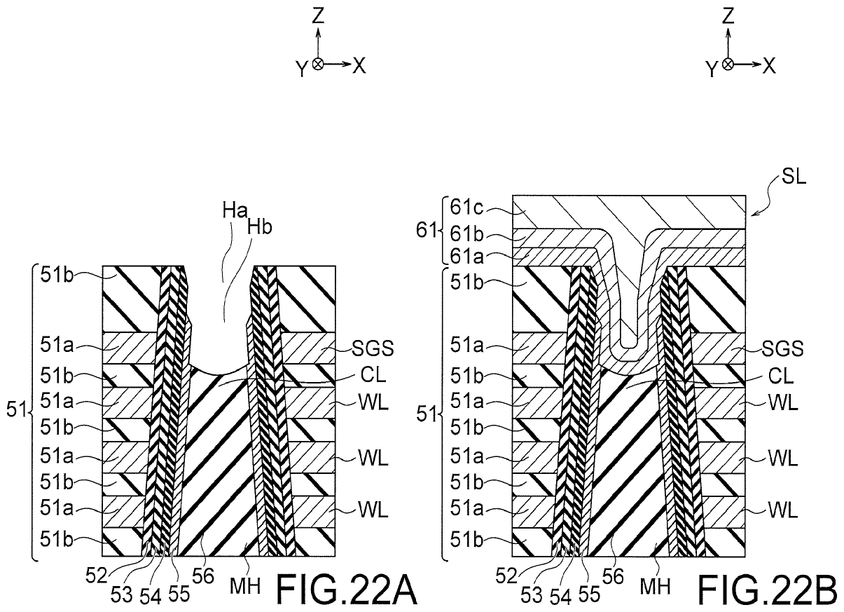

FIGS. 21A to 22B are cross-sectional views illustrating a method of manufacturing the semiconductor device of the comparative example of the second embodiment. FIGS. 21A to 22B illustrate a case where the thickness of the channel semiconductor layer 55 is large.

FIG. 21A illustrates a concave portion Ha formed in the stacked film 51 and the columnar portion CL like the concave portions H1 and H2 illustrated in FIG. 11B and the concave portion H3 illustrated in FIG. 15B. The concave portion Ha is formed by etching back through the process illustrated in FIG. 21A.

Subsequently, the core insulator 56 in the concave portion Ha is processed by etching back (FIG. 21B). As a result, a concave portion Hb is formed in the core insulator 56. Subsequently, the channel semiconductor layer 55 and the like in the concave portions Ha and Hb are recessed through an etching process (FIG. 22A). Subsequently, the interconnect layer 61 is formed on the stacked film 51 and the columnar portion CL (FIG. 22B).

In FIG. 22B, the channel semiconductor layer 55 remains at a position higher than the upper face of the core insulator 56. The interface resistance between the channel semiconductor layer 55 and the interconnect layer 61 is potentially higher when the thickness of the channel semiconductor layer 55 remaining at the position higher than the upper face of the core insulator 56 is large. Such a problem potentially occurs when the etching amount of the channel semiconductor layer 55 in FIG. 22A is too small.

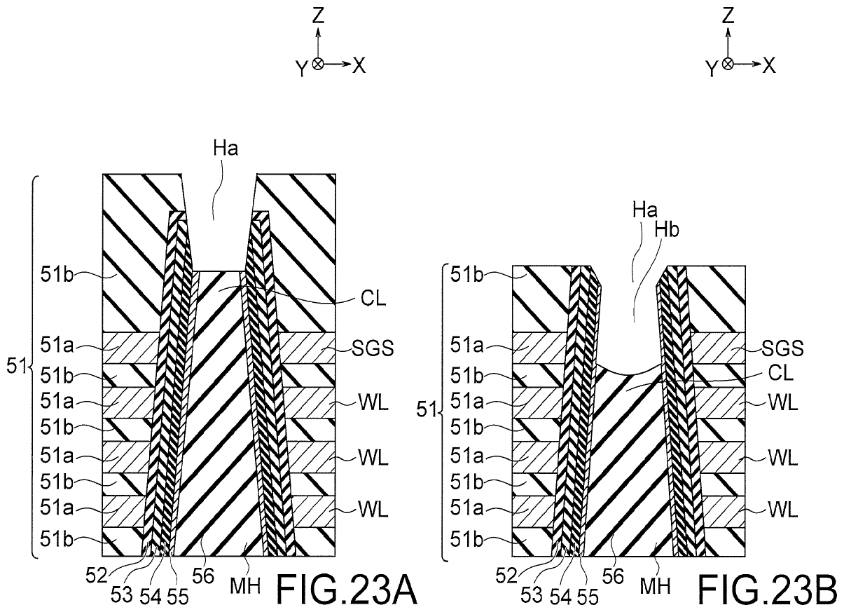

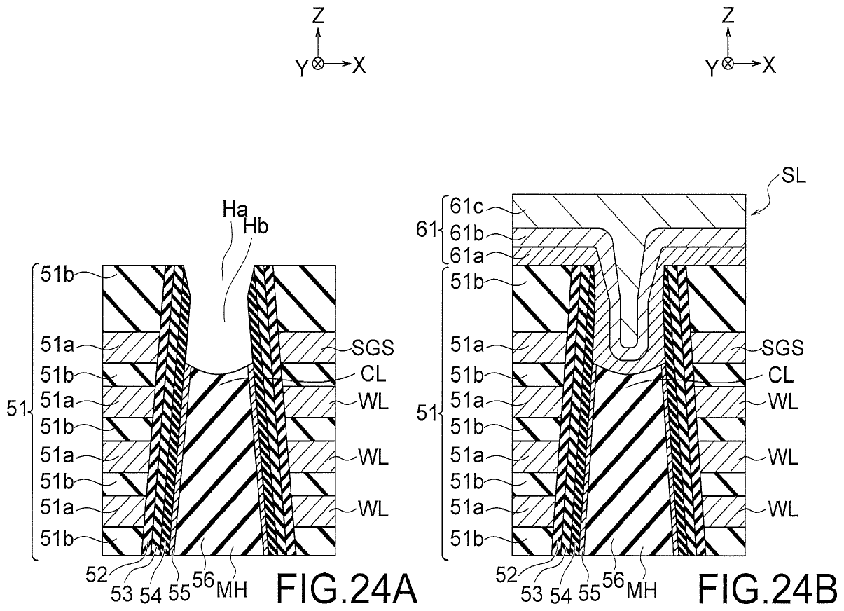

FIGS. 23A to 24B are cross-sectional views illustrating the method of manufacturing the semiconductor device of the comparative example of the second embodiment. FIGS. 23A to 24B illustrate a case where the thickness of the channel semiconductor layer 55 is small.

FIG. 23A also illustrates the concave portion Ha formed in the stacked film 51 and the columnar portion CL. The concave portion Ha is formed by etching back through the process illustrated in FIG. 23A.

Subsequently, the core insulator 56 in the concave portion Ha is processed by etching back (FIG. 23B). As a result, the concave portion Hb is formed in the core insulator 56. Subsequently, the channel semiconductor layer 55 and the like in the concave portions Ha and Hb are recessed by etching process (FIG. 24A). Subsequently, the interconnect layer 61 is formed on the stacked film 51 and the columnar portion CL (FIG. 24B).

In FIG. 24B, the channel semiconductor layer 55 does not remain at a position higher than the upper face of the core insulator 56. In this case as well, the interface resistance between the channel semiconductor layer 55 and the interconnect layer 61 is potentially higher. Such a problem potentially occurs when the etching amount of the channel semiconductor layer 55 in FIG. 24A is too large.

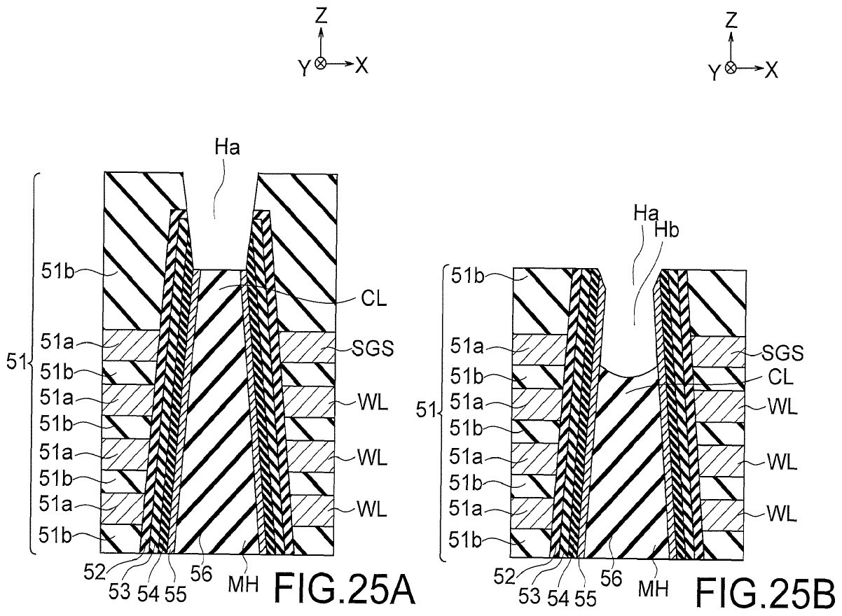

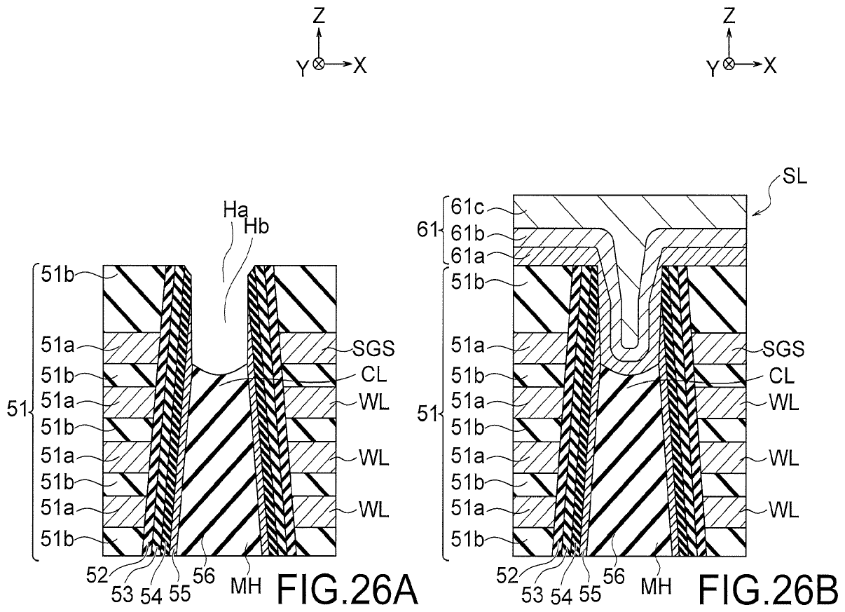

FIGS. 25A to 26B are cross-sectional views illustrating a method of manufacturing the semiconductor device of the second embodiment. In FIGS. 25A to 26B, the thickness of the channel semiconductor layer 55 may be small or large.

FIG. 25A also illustrates the concave portion Ha formed in the stacked film 51 and the columnar portion CL. The concave portion Ha is formed by etching back through the process illustrated in FIG. 25A.

Subsequently, the core insulator 56 in the concave portion Ha is processed by etching back (FIG. 25B). As a result, the concave portion Hb is formed in the core insulator 56. Subsequently, the channel semiconductor layer 55 and the like in the concave portions Ha and Hb is recessed through an etching process (FIG. 26A). Subsequently, the interconnect layer 61 is formed on the stacked film 51 and the columnar portion CL (FIG. 26B).

In FIG. 26B, the channel semiconductor layer 55 remains at a position higher than the upper face of the core insulator 56. However, the thickness of the channel semiconductor layer 55 remaining at the position higher than the upper face of the core insulator 56 decreases with the height from the above-described triple point α (refer to FIG. 19B). This makes it possible to reduce the interface resistance in the case illustrated in FIG. 22B and the interface resistance in the case illustrated in FIG. 24B.

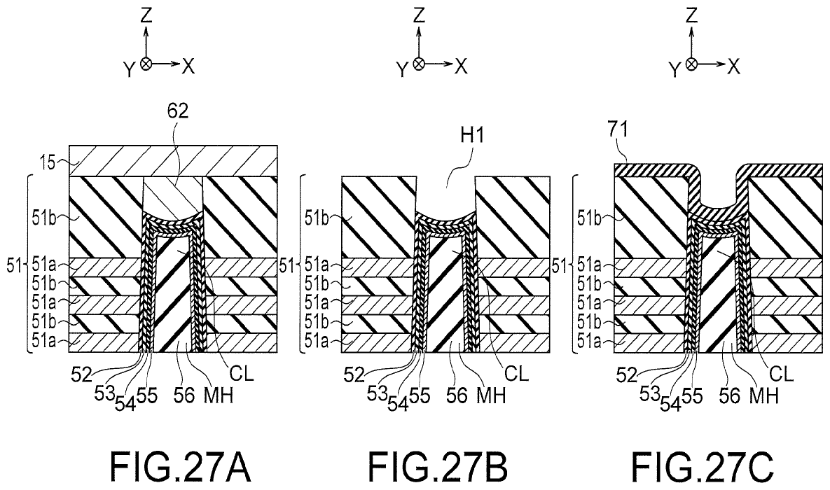

FIGS. 27A to 29C are cross-sectional views illustrating the detailed method of manufacturing the semiconductor device of the second embodiment.

As in FIG. 10B, FIG. 27A illustrates the stacked film 51 right after the array wafer W1 and the circuit wafer W2 are bonded to each other.

Subsequently, the substrate 15 is removed by wet etching (FIG. 27B). In a case where the substrate 15 and the sacrifice layer 62 are a semiconductor substrate and a semiconductor layer, respectively, the sacrifice layer 62 is removed as well by the wet etching. As a result, the concave portion H1 is formed in a region from which the sacrifice layer 62 is removed, and the block insulator 52 of each columnar portion CL is exposed in the concave portion H1.

Subsequently, a spacer layer 71 is formed on the stacked film 51 and the columnar portion CL (FIG. 27C). As a result, the spacer layer 71 is formed on the side face of the stacked film 51 and the upper face of the columnar portion CL in the concave portion H1. The spacer layer 71 is, for example, an SiO₂ film.

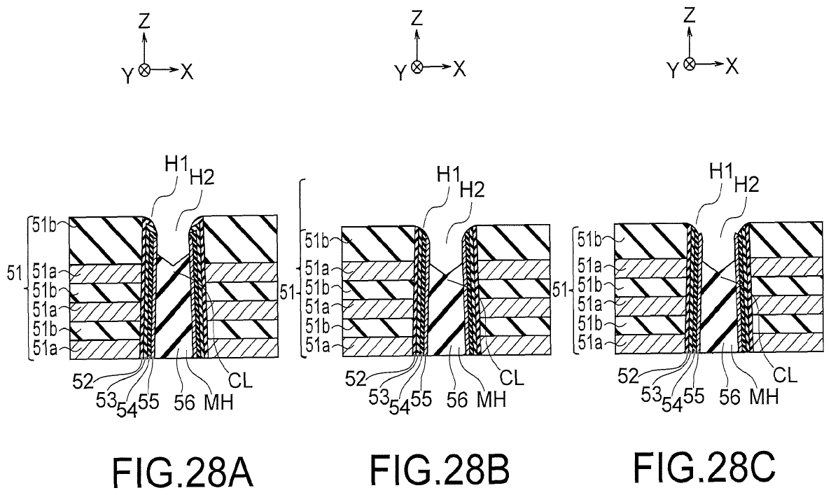

Subsequently, the spacer layer 71, the block insulator 52, the charge storage layer 53, the tunnel insulator 54, the channel semiconductor layer 55, and the core insulator 56 are processed by etching back from the concave portion H1 (FIGS. 28A and 28B). As a result, the spacer layer 71 is removed and the concave portion H2 is formed in the columnar portion CL. The shape of the columnar portion CL changes from FIG. 27C to FIG. 28A and further changes from FIG. 28A to FIG. 28B. The above-described etching back is performed by, for example, anisotropic etching such as SiO₂ non-selective dry etching.

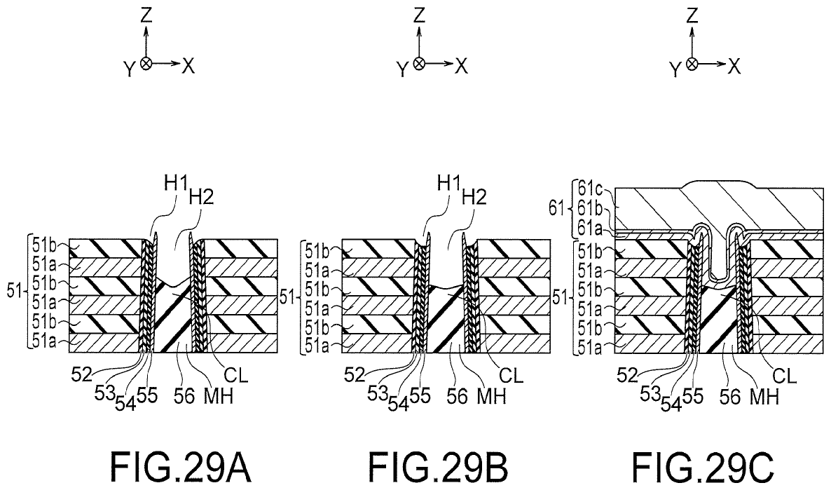

Subsequently, the block insulator 52, the charge storage layer 53, the tunnel insulator 54, the channel semiconductor layer 55, and the core insulator 56 are recessed through an etching process from the concave portions H1 and H2 (FIGS. 28C, 29A, and 29B). As a result, the shape of the columnar portion CL sequentially changes from FIG. 28B to FIG. 28C, FIG. 29A, and FIG. 29B. The above-described etching process is performed by, for example, isotropic etching such as SiO₂ selective wet etching. In this case, the selection ratio of SiO₂, SiN, and Si is set to, for example, 10:10:1.5. Through the above-described etching process, the thickness T of the channel semiconductor layer 55 at a position higher than the triple point α can be decreased with the height from the triple point α.

Subsequently, the lower barrier metal layer 61a, the upper barrier metal layer 61b, and the interconnect material layer 61c are sequentially formed on the stacked film 51 and each columnar portion CL (FIG. 29C). As a result, the interconnect layer 61 is formed on the columnar portion CL and electrically connected to the channel semiconductor layer 55 in the columnar portion CL.

As described above, in the present embodiment, the thickness T of the channel semiconductor layer 55 at a position higher than the triple point α decreases with the height from the triple point α. Thus, the present embodiment makes it possible to reduce the interface resistance between the channel semiconductor layer 55 and the interconnect layer 61.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a stacked film including a plurality of electrode layers and a plurality of first insulators alternately in a first direction, a top layer of the stacked film being a second insulator that is one of the plurality of first insulators;
a columnar portion including a third insulator provided on a side face of the stacked film, a charge storage layer provided on a side face of the third insulator, a fourth insulator provided on a side face of the charge storage layer, and a first semiconductor layer provided on a side face of the fourth insulator, the columnar portion being provided in the stacked film,
a metal layer provided on the stacked film and the columnar portion, electrically connected to the first semiconductor layer, and including one or more layers,
wherein
an upper end of the columnar portion is provided at a height between an upper face and a lower face of the second insulator, and
a lower end of a highest layer among the one or more layers is provided at a position lower than the upper face of the second insulator.

2. The device of claim 1, wherein the lower end of the highest layer is provided at a position higher than the lower face of the second insulator.

3. The device of claim 1, wherein the highest layer is an interconnect material layer in an interconnect layer that includes the metal layer.

4. The device of claim 3, wherein the one or more layers further include a barrier metal layer provided below the interconnect material layer.

5. The device of claim 1, further comprising a second semiconductor layer provided between the first semiconductor layer and the metal layer.

6. The device of claim 1, wherein an upper face of the columnar portion is tilted relative to a plane orthogonal to the first direction.

7. The device of claim 1, wherein the metal layer is included in a source line, and a highest electrode layer among the plurality of electrode layers is included in a source-side select line.

8. The device of claim 1, wherein the columnar portion further includes a fifth insulator provided on a side face of the first semiconductor layer.

9. The device of claim 8, wherein an upper end of the first semiconductor layer is provided at a position higher than a triple point where the first semiconductor layer, the fifth insulator and the metal layer contact one another.

10. The device of claim 9, wherein a thickness of the first semiconductor layer at a position higher than the triple point is smaller than a thickness of the first semiconductor layer at a position lower than the triple point.

11. The device of claim 10, wherein the thickness of the first semiconductor layer at a position higher than the triple point decreases with a height from the triple point.

12. A method of manufacturing a semiconductor device, comprising:
forming a stacked film that includes a plurality of first layers and a plurality of first insulators alternately in a first direction;
forming a columnar portion in the stacked film, the columnar portion including a third insulator provided on a side face of the stacked film, a charge storage layer provided on a side face of the third insulator, a fourth insulator provided on a side face of the charge storage layer, and a first semiconductor layer provided on a side face of the fourth insulator;
replacing the plurality of first layers with a plurality of electrode layers; and
forming a metal layer on the stacked film and the columnar portion, the metal layer being electrically connected to the first semiconductor layer and including one or more layers,
wherein
a top layer of the stacked film is a second insulator that is one of the plurality of first insulators, when forming the metal layer,
an upper end of the columnar portion is provided at a height between an upper face and a lower face of the second insulator, and
a lower end of a highest layer among the one or more layers is provided at a position lower than the upper face of the second insulator.

13. The method of claim 12, wherein the lower end of the highest layer is provided at a position higher than the lower face of the second insulator.

14. The method of claim 12, wherein
the stacked film is formed on a first substrate,
the columnar portion is formed in the stacked film on the first substrate,
the first substrate is bonded to a second substrate to sandwich the stacked film and the columnar portion, and is removed after being bonded to the second substrate, and
the metal layer is formed on the stacked film and the columnar portion, after the first substrate is removed.

15. The method of claim 14, further comprising forming a first opening in the stacked film on the first substrate,
wherein the columnar portion is formed in the first opening.

16. The method of claim 15, further comprising forming a second layer on the first substrate in the first opening,
wherein the columnar portion is formed on the second layer in the first opening.

17. The method of claim 16, wherein the second layer is formed by epitaxial growth from the first substrate.

18. The method of claim 16, wherein
the second layer is removed after the first substrate is bonded to the second substrate, and
the metal layer is formed on the stacked film and the columnar portion, after the first substrate and the second layer are removed.

19. The method of claim 18, wherein the second layer is removed so that a second opening is formed on the columnar portion in the stacked film.

20. The method of claim 12, wherein the metal layer is formed to be included in a source line, and a highest electrode layer among the plurality of electrode layers is formed to be included in a source-side select line.
